(19) United States
(12) Patent Application Publication
(10) Pub. No.: US 2003/0075777 A1
(43) Pub. Date: Apr. 24, 2003

(54) Film for a film capacitor and film capacitor

(76) Inventors: Martin Carlen, Niederrohrdorf (CH); Christian Ohler, Baden (CH); Jakob Rhyner, Davos (CH)

Correspondence Address: BURNS, DOANE, SWECKER & MATHIS, L.L.P., P.O. Box 1404, Alexandria, VA, 22313-1404, US

(21) Appl. No.: 10/274,115

(22) Filed: Oct. 21, 2002

(30) Foreign Application Priority Data
Oct. 23, 2001 (EP) 01811034.6

(51) Int. Cl. H01L 29/00

(52) U.S. Cl. 257/532

(57) ABSTRACT

Film capacitors have a thin carrier film (1) as dielectric. The surfaces of the carrier films are provided with conductor layers (2)—serving as electrodes—made of metal or made of a nonmetallic conductor. If the capacitor is charged during operation, electric fields with large field strengths can arise at the edges of the conductor layers (2), which can lead to breakdowns. The invention is essentially distinguished by the fact that an edge zone coating (3) is present at the edges of the electrode-forming conductor layer (2), which edge zone coating is only partly charged in the time periods—for example of the alternating-current period—which are critical for changes in the applied voltage. To that end, the edge zone coating of the film must have a surface conductivity which is less than the surface conductivity of the conductor layer. The only partial charging of the edge zone coating has the result that the potential profile has scarcely any discontinuities and large field strength increases can thus be avoided.

### TECHNICAL FIELD

The present invention relates to a film for a film capacitor according to the preamble of claim 1 and to a film capacitor and a method for producing a film for a film capacitor.

### PRIOR ART

The invention concerns film capacitors. In addition, it can also be used for other elements of electrical engineering, for example for bushings of transformers or switches and insulation systems of cables and cable end terminations, and also for ceramic and other capacitors. Specifically, it concerns the question of avoiding large electric field strengths at electrode edges.

Film capacitors have a thin plastic film as dielectric. The film surfaces are provided with coatings—serving as electrodes—made of metal or made of a nonmetallic conductor. The conductor layers are usually Al or Zn alloys applied in a vacuum. They have thicknesses in the range of 10-20 nm, as a result of which self-healing can occur in the event of local electrical breakdowns.

Segmented metal coatings are known from the prior art. The individual segments of the metal coating are isolated from one another by trench-like cutouts. The segments are connected by conductor bridges with a small cross section. These conductor bridges serve as protection devices which, in the event of an electrical breakdown, isolate the affected segment from the remaining segments. If a local breakdown occurs, the power liberated at the breakdown location is limited by the protection devices, as a result of which relatively great damage can be avoided.

Also known are multilayers of capacitor films for internal series circuits, comprising electrodes with and also without segmentation. The electrodes have zones with high electrical resistance, where the capacitance is produced, and zones with low electrical resistance at the locations of the connecting areas.

The electrode thickness in the case of these film capacitors according to the prior art is only a few nanometers or a few dozen nanometers. Therefore, the electrode has a very sharp edge. With this electrode thickness, it is not possible to round the edge and to reduce the field strength of the electric field through an appropriately chosen curve radius of the edge. At the edge, the electric field thus has a large field strength and it may be that a current is initiated into the film and a breakdown occurs.

In the case of direct-current capacitors, the problem of the increased field strength at the edges exists primarily during a short time after the charging of the capacitor and during changes in the applied voltage. If the voltage is kept constant, a space charge forms and compensates for the increased field. For alternating-current capacitors no such compensation is produced, or it is much slower on account of the periodically changing polarity. Therefore, the excessive field strength increase at the edges is a much greater problem in the case of alternating-current capacitors.

EP 880 153 describes a metallized capacitor film having a metal layer zone with a sheet resistance of 1-15 Ω and an edge zone having a metallization thickness that decreases continuously toward the edge. The edge zone prevents the presence of a sharp edge and contributes to avoiding an electrical breakdown at the edge of the metal layer. The metallization of the edge zone is coated by means of a vacuum deposition process, the corresponding area first being coated with an oil film. For impregnation, the same or a matching other oil is used, for example silicone oil.

Such an edge zone having a continuously decreasing metallization thickness is difficult to produce on account of its small width of approximately 0.02-1 mm. This is true particularly if the capacitor film has a large extent. If the metallizations are thin, a continuous layer is not possible since metal islands form in the case of excessively small thicknesses.

### SUMMARY OF THE INVENTION

It is an object of the invention to provide a film for a film capacitor or for another capacitive element, which does not tend toward breakdowns even at comparatively high applied voltages, and which does not tend toward creeping discharges or toward electro-hemical erosion at electrode edges.

This object is achieved by means of a film as defined in claim 1.

The invention likewise relates to a capacitor in accordance with claim 9 and a method according to claim 12.

Advantageous refinements of the film and of the capacitor and of the production method emerge from the dependent claims.

The invention is essentially distinguished by the fact that an edge zone coating is present at the edges of the electrode-forming conductor layer, which edge zone coating is only partly charged in the time periods—for example of the alternating-current period—which are critical for changes in the applied voltage. To that end, the edge zone coating of the film must have a surface conductivity which is less than the surface conductivity of the conductor layer. The only partial charging of the edge zone coating has the result that the potential profile has scarcely any discontinuities and large field strength increases can thus be avoided. The edge zone may be considered as a field strength gradient zone.

The edge zone coating is only partly charged if the capacitor voltage changes within a characteristic time period. Accordingly, the resistance of the zone is adapted to the characteristic frequency of the change.

If the resistance were too high, the edge zone would not be charged, and the excessive field strength increase at the edge of the metallization would remain. On the other hand, if the resistance were too low, the edge zone would be completely charged and the problem of the excessive field strength increase would only be transferred to the edge of the edge zone.

Thus, an important parameter is the RC time of the electrode (that is to say the product τ=R*C, if R represents a characteristic resistance and C the capacitance). The RC time is intended to vary locally and be much greater at the electrode edges—that is to say in the edge zone coating—than in the center of the electrode or of the segments. In accordance with preferred embodiments of the invention, the RC time is varied by a plurality of orders of magnitude. The resistivity in the region of the electrode edge should vary in the range from ρ=4*10⁻³ to 1*10⁶ Ω*cm.

The customary sheet resistance of a self-healing capacitor electrode is of the order of magnitude of Rₛ=5-20 Ω. It is optimally chosen such that the losses of the electrode at most make the same contribution to the total of the losses as does the loss factor of the dielectric (tan(δ)=10⁻⁴ to 10⁻² for most polymeric capacitor films), so that the electrode makes little contribution to the total loss. It follows from this that the sheet resistance is in the range Rₛ=1-100 Ω. This range also results from practical reasons. Thicker metallizations (corresponding to smaller resistances) lead to difficulties in the self-healing process. Larger areas with thinner metallizations are difficult to realize with good quality, since unconnected metal islands often form.

The RC time of a capacitor having a metallized polypropylene film approximately 10 μm thick (capacitance: 0.2 nF/cm²) and a sheet resistance of Rₛ=10 Ω is τ=2*10⁻⁹ s. Therefore, the entire capacitor electrode is completely charged and discharged within a 50 Hz cycle; the electrode edge will also be at the electrode potential. Since the electrode thickness is only a few nanometers or a few dozen nanometers, the electrode has a very sharp edge. Therefore, the field strengths at the edge are very high.

In accordance with preferred embodiments of the invention, however, the RC time in the edge zone is of the same order of magnitude as the period of the applied AC voltage or of the characteristic time of a change in the capacitor voltage. This is because in this case the edge zone exhibits a gradual potential profile; toward the edge the potential approaches its average value with respect to time. This condition, together with the width of the contact zone, defines the desired sheet resistance. The following thus expediently holds true:

RC=Rₛ*(b/l)*Cₛ*(b*l)=Rₛ*Cₛ*b²≈T=1/f

if Cₛ is the capacitance per unit area, Rₛ is the sheet resistance, T=1/f (f=frequency) is the period of the change in the capacitor voltage and b is the width of the edge zone coating and l is the arbitrarily selected length of an edge zone coating strip. In the case of DC capacitors, the duration of a voltage transient replaces the period T.

Two limits can be specified for a suitable choice for the width of the edge zone. The thickness of the dielectric film may be considered as the lower limit, that is to say b≧approximately 10 μm, while practically b<5 mm also holds true.

Limit values also result in practice for the thickness h of the edge zone coating. The minimum is 1 nm, since thinner layers are virtually impossible to produce contiguously. Thus, a layer thickness variation which decreases continuously down to zero over the edge zone width is in no way required. A discontinuous or stepwise layer thickness variation is sufficient according to the invention, preferably only one step being formed and, consequently, it being possible to talk of an unambiguous, homogeneous layer thickness h. The maximum thickness is approximately 1 μm since thicker coatings cause problems in the winding of the capacitor, and also impair the self-healing ability and the energy density of the capacitor.

A main advantage of the invention is that electrically nonconductive or free regions which surround and electrically insulate the electrodes can be made smaller, i.e. less wide. As a result, the electrode area can again be enlarged with the film area remaining the same.

### BRIEF DESCRIPTION OF THE DRAWINGS

The invention is explained in even more detail below using exemplary embodiments and with reference to highly diagrammatic drawings, in which:

FIGS. 1a and 1b each show a film coated on one side in cross section,

FIG. 2 shows a plan view of a film

FIG. 3 shows the potential profile in the film coating

FIG. 4 shows a plan view of a further film

FIGS. 5a and 5b show layers of a multilayer film capacitor in plan view and in cross section.

### WAYS OF EMBODYING THE INVENTION

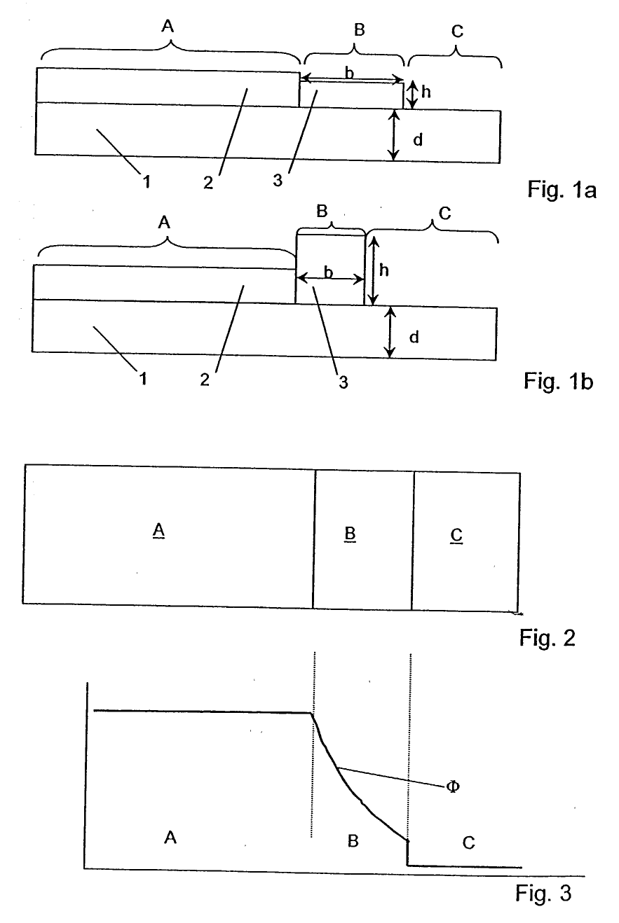

FIGS. 1a and 1b diagrammatically show a cross section through a film according to the invention for a film capacitor. A carrier film 1 serves as a mechanical carrier and is electrically insulating and dielectric. It comprises a plastic, for example a polymer such as polyethylene, polystyrene, polypropylene, polycarbonate, PET, PEN, cellulose acetate, polyesters, an epoxy resin, a polysulfone, or another plastic or paper and is approximately 2-30 μm thin. A conductor layer 2 applied thereon is formed as a metal layer or as a conductive plastic. The conductor layer 2 does not completely cover one surface of the carrier film 1, so that there is a free edge. In FIGS. 1 and 1b, just as in the following figures, the regions into which the film surface is subdivided by different coatings are designated by upper-case letters. Regions of the surface in which the carrier film 1 is provided with the conductor layer 2 are designated by A, regions in which it is free of a coating—the free regions—are designated by C. Situated between the regions A of the conductor layer 2 and the free regions C is an edge zone B, where the carrier film is provided with an edge zone coating 3.

The edge zone coating 3 is produced from a material having a comparatively low electrical conductivity. Its width b is between 10 μm and 5 mm, preferably between 100 μm and 2 mm. The thickness h of the edge zone coating 3 may be less than or greater than the thickness of the conductor layer 2. FIGS. 1a and 1b each illustrate an example of an edge zone coating which is thicker and of one which is thinner than the conductor layer 2.

As an alternative to the arrangement depicted, the material of the edge zone coating 3 may also completely or partly cover the conductor layer 2 in addition to the edge zone B. Furthermore, the edge zone coating may also be chosen with a width such that the material of the edge zone coating completely covers the original free regions, i.e. that a free region is no longer present at all at least in regions, but the conductivity of the edge zone coating is chosen such that the charge cannot extend over the entire width within a half-cycle.

FIG. 2 illustrates a detail from a film according to the invention with the region A covered by the conductor layer, the edge zone B and the free region C in plan view.

The edge zone coating is intended to be charged partially, but not completely, during an alternating-current cycle. What is thus intended to be achieved is that the potential profile runs more or less continuously from the edge of the conductor layer 1 toward the edge, which makes it possible to avoid large electric field strengths. This means that the RC time of the edge zone coating must be of the same order of magnitude as the period T−1/f (f=frequency) of the AC voltage. In the case of DC capacitors, the duration of a voltage transient replaces the period T in the discussion below. The following thus results

RC=Rₛ*(b/l)*Cₛ*(b*l)=Rₛ*Cₛ*b²≈T=1/f

if Cₛ is the capacitance per unit area, Rₛ is the sheet resistance and l is the arbitrarily selected length of an edge zone coating strip.

The following results from this for the resistivity of the edge zone coating:

ρ=h*Rₛ≈h/(f*b²*Cₛ)=h*d/(f*b²*ε*ε₀)

if d is the thickness of the dielectric carrier film and ε is its dielectric constant. Thus, by inserting the value of 1/ε₀ (10¹³ Vcm/As) and relaxing the relationship RC=1/f that is strictly followed above, a realistic condition results for the edge zone resistance for a predetermined geometry:

ρ=[1*10¹² . . . 1*10⁶]*(h*d)/(f*b²*ε)(Ω*cm),

if the frequency f is specified in Hz. The following is preferably chosen

ρ=[3*10¹² . . . 1*10¹⁵]*(h*d)/(f*b²*ε)(Ω*cm)

In accordance with a particularly preferred example, the following holds true

ρ=[7*10¹² . . . 1*10¹⁴]*(h*d)/(f*b²*ε)(Ω*cm).

Analogous relationships apply to the sheet resistance Rₛ=ρ/h, that is to say preferably

Rₛ=[3*10¹² . . . 1*10¹⁵]*d/(f*b*ε)(Ω).

If the abovementioned customary dimensions of the edge zone coating are taken into account the following results, for example

ρ=[4*10⁶ . . . 1*10¹⁷]d)/(f*ε)(Ω*cm)

(d in cm).

If the film capacitor is operated at 50 Hz, the following is preferably obtained:

ρ=[6*10¹⁰ . . . 2*10¹³]*(h*d)/(b²*ε)(Ω*cm)

or:

ρ=[2*10⁴ . . . 2*10¹⁵]d/ε(Ω*cm).

If the above conditions on the resistivity and the dimensions of the edge zone coating are met, then the potential Φ of the fully charged capacitor decreases (or increases) continuously within the edge zone B as a function of the distance from the conductor layer, as is illustrated in FIG. 3. In this case, it suffices if the potential within the edge zone is attenuated to a fraction, preferably at most a third, of its value within the conductor layer. This is because, with the exception of the abovementioned case of a lack of a free region, it is in no way absolutely necessary to reduce the potential down to zero within the edge zone.

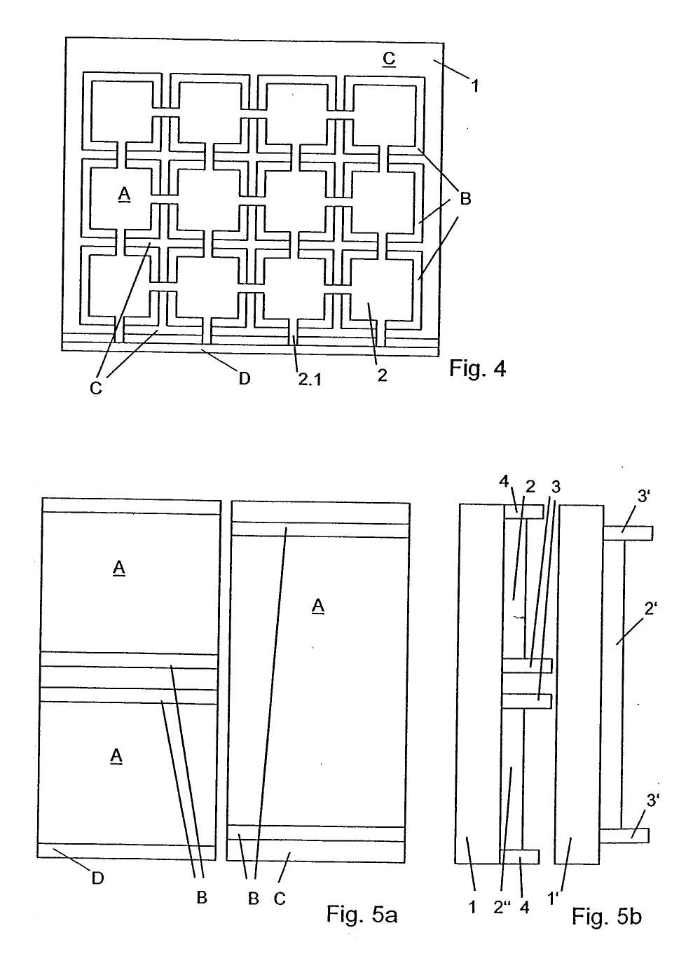

FIG. 4 shows a segmented capacitor film. The conductor layer 2 has a multiplicity of segments connected by conductor bridges 2.1. Free regions (region C) extend in between and also at the edge of the film. Edge zones B according to the invention are situated between the conductor layer 2 (corresponding to the region A) and the region C. The figure also illustrates a region D containing an edge strengthening.

FIGS. 5a and 5b show films of a film capacitor with an internal series circuit. Such an internal series circuit can be effected in a simple way by a conductor layer of one film being located opposite two conductor layers of a second film that are not directly connected to one another electrically. The figure shows two films each having a carrier film 1, 1′. The capacitance formed between a first conductor partial layer 2 of the first film and a conductor layer 2′ of the second film layer is connected in series with the capacitance formed between the conductor layer 2′ of the second film and a second conductor partial layer 2″ of the first film. In addition to the edge zone coatings 3, 3′ forming the edge zone, edge strengthenings 4 are also depicted in the figure. Depending on the construction of the capacitor (winding, etc.), the two films may also be segments of a single film.

The edge zone coating can be produced in various ways. In accordance with a first variant, an alloy having a reduced electrical conductivity or a semiconductor can be applied to the carrier film in a targeted manner at the edges of the conductor layer. This is done using methods as are already known per se for the application of strips tenths of millimeters or millimeters wide (for example from the production of capacitor films, or else printed circuit boards, etc.), for example with the aid of a mask, with the aid of photolithographic methods, etc. A carbon coating or a polymer coating can also be applied. Finally, the edge zone coating can also be formed by a conductive liquid (oil, ink, etc.) which, for example, can subsequently also be made mechanically solid by a gel-forming process.

A further variant provides for the intentional impairment of conductor properties of the conductor layer at the edges thereof. This is done, for example, chemically by targeted exposure of the corresponding regions B to a reactive atmosphere (oxidation, etc.), by plasma treatment, etc. However, it can also be effected mechanically or by heating with a laser.

In accordance with another variant, the uncovered surface of the carrier film is made conductive, for example by surface carbonization by laser pyrolysis, etc.

A current path structure as described in the published German patent application DE 198 56 457, for example, may run (not illustrated in the drawings) within the conductor layer.

1. A film for a film capacitor or another element of electrical engineering having a dielectric carrier film (1, 1′) and at least one conductor layer (2, 2′) applied thereon, the conductor layer (2, 2′) not completely covering the carrier film (1, 1′), characterized in that an edge zone (B) is present adjoining the conductor layer (1, 1′) at least in regions, in which edge zone the carrier film (1, 1′) is provided with an edge zone coating (3) made of an electrically conductive material, the sheet resistance in the edge zone (B) being greater than the sheet resistance of the conductor layer (1, 1′)

2. The film as claimed in claim 1, characterized in that the thickness of the edge zone coating (3) decreases discontinuously to zero.

3. The film as claimed in claim 2, characterized in that the edge zone coating (3) has an essentially homogeneous thickness.

4. The film as claimed in one of claims 1 to 3, characterized in that the edge zone coating (3) comprises material of the conductor layer (2) that is at least partly oxidized, plasma-treated, mechanically damaged or heated by a light beam.

5. The film as claimed in one of claims 1 to 3, characterized in that the edge zone coating (3) comprises a metallic alloy having a low conductivity, a semiconductor material, a graphite- or carbon-like coating or a conductive polymer.

6. The film as claimed in one of claims 1 to 3, characterized in that the edge zone coating (3) comprises a conductive oil or a conductive ink, the oil or the ink preferably being fixed by a gel-forming process.

7. The film as claimed in one of claims 1 to 3, characterized in that the edge zone coating (3) comprises a surface layer of the dielectric film that is modified by laser pyrolysis, for example.

8. The film as claimed in one of the preceding claims, characterized in that the material of the edge zone coating completely or partly covers the conductor layer (2) or covers the regions (C) not covered by the conductor layer.

9. A film capacitor having electrodes and a dielectric arranged between the electrodes, characterized in that at least one electrode and the dielectric are formed by a film as claimed in one of claims 1 to 8.

10. The film capacitor as claimed in claim 9, characterized in that it is formed as an alternating-current capacitor for alternating current with an average alternating-current frequency f, and in that the product of the electrical resistance R of the edge zone coating and the local capacitance C is of the same order of magnitude as the inverse of the alternating-current frequency.

11. The film capacitor as claimed in claim 10, characterized in that 10¹²*d/(f*b²*ε)<Rₛ<10¹⁶*d/(f*b²*ε) holds true for the sheet resistance Rₛ in Ω of the edge zone coating, if d is the thickness of the dielectric film in cm, b is the width and h the thickness of the edge zone coating in cm and ε is the dielectric constant of the dielectric film and the frequency f is specified in Hz.

12. A method for producing a film for a film capacitor, a dielectric carrier film (1, 1′) being provided, which is provided with a partly covering conductor layer (2, 2′, 2″), characterized in that, at the edge of the regions (A) covered by the conductor layer, the carrier film (1, 1′) is provided with an edge zone coating (3) made of an electrically conductive material, the sheet resistance of the edge zone coating (3) being greater than the sheet resistance of the conductor layer (1, 1′).

13. The method as claimed in claim 12, characterized in that, as edge zone coating (3), an electrically weakly conductive material is coated after the application of the conductor layer (2) in a targeted manner at the edges of the conductor layer (2).

14. The method as claimed in claim 13, characterized in that the edge zone coating is produced by reducing the conductivity of the conductor layer (2) in a region (B) at the edges of said layer by chemical or mechanical methods.

15. The method as claimed in claim 14, characterized in that the edge zone coating is produced by the surface of the carrier film being made conductive, for example by surface carbonization, in a region (B) adjoining the edges of the conductor layer (2).
